(19) United States
(12) Patent Application Publication
(10) Pub. No.: US 2002/0076072 A1
(43) Pub. Date: Jun. 20, 2002

(54) Software implemented loudness normalization for a digital hearing aid

(76) Inventor: Leonard E. Cornelisse, Waterloo (CA)

Correspondence Address: Bhupinder S. Randhawa, Bereskin & Parr, Box 401, 40 King Street West, Toronto, ON, M5H 3Y2, CA

(21) Appl. No.: 09/985,976

(22) Filed: Nov. 7, 2001

Related U.S. Application Data
(63) Continuation of application No. 09/299,082, filed on Apr. 26, 1999, now abandoned.

(51) Int. Cl. H03G 3/00; H04R 25/00

(52) U.S. Cl. 381/312; 381/104

(57) ABSTRACT

A digital user loudness normalization control is provided for implementation within a digital hearing aid or other personal amplification device having a digital signal processor. The digital hearing aid may be either a single frequency channel system or a multi-channel system. The control alters the input/output characteristic or loudness function of the single channel device or in each channel of a multi-channel device in response to the loudness control signal and the input signal level. The control system can be programmed to provide numerous modes of operation including curvilinear compression, input compression, output compression, and combinations thereof for correcting an individual's hearing impairment. In an alternative embodiment, the control for an amplification device having multiple frequency channels may include an independent loudness control signal for each frequency channel.

This application is a continuation of U.S. patent application Ser. No. 09/299,082, which is incorporated herein by this reference.

### FIELD OF THE INVENTION

The present invention relates to the fields of hearing aids and personal amplification devices. In particular, the present invention relates to loudness and volume control in digital hearing aid systems.

### BACKGROUND OF THE INVENTION

Hearing aid devices which exhibit a linear compression characteristic may not adequately restore normal loudness perception where the user's loudness growth is abnormal.

At the same time, non-linear or curvilinear WDRC (wide dynamic range compression) hearing aids typically do not include a user-adjustable volume control. In order to fit such hearing aids accurately, an accurate measurement or estimate of the hearing aid user/wearer's loudness perception is required. However, not all users can perform the loudness perception task, the procedure is very time consuming, and the estimate of loudness perception may be inaccurate. On the other hand, volume controllable devices with input or output compression may not match the user or wearer's preferred or required listening levels.

At present, very few hearing aids offer curvilinear compression. Furthermore those aids which provide non-linear compression do not include a user control to adjust the curvilinearity of the compression characteristics (i.e. of the input/output function).

U.S. Pat. No. 4,118,604 to Yanick discloses a volume control for a hearing aid which operates to vary the audio output of the hearing aid as well as the frequency response of the aid. Adjustment of the volume control varies the frequency response (i.e. slope and centre frequency) of an active bandpass filter in the hearing aid. The setting of the volume control also serves to vary the compression ratio of the input/output response of the hearing aid in a compression region of the response. In this manner, the hearing aid attempts to match the frequency response of a normal ear in response to the setting of the volume control, which will be dependent on the overall intensity or loudness of input speech. Yanick discloses equalizing the input loudness contour curves, i.e. the variation of the input sound pressure level (SPL) over the acoustic range of frequencies, so as to avoid having stronger components in the input reduce the gain of the input/output characteristic and hence control compressor operation. As a result, compression of the input/output characteristic (i.e. the compression region of that function) begins at lower input signal levels for higher input frequencies—compression occurs primarily at higher frequencies.

However, Yanick does not measure the input signal levels, but merely relies generally on the volume control setting to be indicative of the loudness of the input. This is problematic in environments where the loudness of input acoustic signals is constantly varying. Yanick also does not provide a curvilinear compression characteristic. For a given volume control setting, the compression characteristic is linear. Moreover, Yanick does not adjust the input/output function of the hearing aid in response to loudness within different frequency bands or ranges. Yanick simply attempts to equalize the input loudness curves across the acoustic spectrum, and then control the input/output function of the hearing aid according to the equalized loudness of the input. Furthermore, the action of the hearing aid device disclosed by Yanick is hard-wired and so it is very difficult to change the control characteristics of the device.

Also, hearing-impaired listeners often have different degrees of hearing loss at different audible frequencies, and therefore require frequency dependent amplification characteristics. A user-adjustable loudness control may therefore require a different mode of operation in the various frequency regions. Practically, this means that a user-adjustable volume control should have independent characteristics for each channel in a multi-channel hearing aid.

There is therefore a need for a user-adjustable loudness control for a hearing aid (or other personal amplification device generally) which provides adjustable compression characteristics. A control which adjusts the compression characteristics independently in different frequency channels or bands would provide further advantages.

### SUMMARY OF THE INVENTION

In a first aspect the prsent invention provides a method of generating an acoustic output signal from an acoustic input signal in accordance with an input/output characteristic, said method comprising the steps of: (a) converting the acoustic input signal into a digital acoustic input signal; (b) transforming the digital acoustic input signal into one or more frequency domain input signals; (c) detecting the magnitude of each of the one or more frequency domain input signals; (d) providing an adjustable digital loudness control signal; (e) for each of the one or more frequency domain input signals, determining a gain value in response to the loudness control signal and the magnitude of the frequency domain input signal, each of the gain values being determined according to said input/output characteristic; (f) for each of the one or more frequency domain input signals, multiplying the frequency domain input signal by the corresponding gain value to provide one or more processed frequency domain signals; (g) transforming the one or more processed frequency domain signals into a digital acoustic output signal; and (h) converting the digital acoustic output signal into the acoustic output signal.

Preferably, the method further comprises the step of (i) independently adjusting the digital loudness control signal in accordance with the preferences of a hearing impaired individual. Also steps (c), (e), and (f) are advantageously carried out by means of a programmable digital signal processor.

In another aspect, the present invention provides a method of generating an acoustic output signal from an acoustic input signal in accordance with a composite input/output characteristic, said method comprising the steps of: (a) converting the acoustic input signal into a digital acoustic input signal; (b) transforming the digital acoustic input signal into N frequency domain input signals, N being a positive integer greater than or equal to two; (c) detecting the magnitude of each of the N frequency domain input signals; (d) providing N adjustable digital loudness control signals, each of the loudness control signals corresponding to one of the frequency domain input signals; (e) for each frequency domain input signal, determining a gain value in response to the corresponding loudness control signal and the magnitude of said frequency domain input signal, the N gain values being determined according to N input/output characteristics and the composite input/output characteristic being formed from said N input/output characteristics; (f) multiplying each frequency domain input signal by the gain value to provide N processed frequency domain signals; (g) transforming the N processed frequency domain signals into a digital acoustic output signal; and (h) converting the digital acoustic output signal into the acoustic output signal.

In a further aspect, the present invention provides a loudness normalization control system for receiving an acoustic input signal and providing an acoustic output signal according to an input/output characteristic, said loudness normalization control system comprising: (a) an analog-to-digital converter for receiving the acoustic input signal and providing a digital acoustic input signal in response; (b) an analysis filter for receiving the digital acoustic input signal and providing one or more frequency domain input signals in response; (c) a level detector for receiving the one or more frequency domain input signals and providing one or more level values representative of the magnitude of the one or more frequency domain input signals; (d) a control stage for providing an adjustable digital loudness control signal; (e) a gain providing stage for receiving the level values and the adjustable digital loudness control signal and, for each of the one or more frequency domain input signals, determining a gain value in response to the loudness control signal and the magnitude of the frequency domain input signal, each of the gain values being determined according to said input/output characteristic; (f) a multiplier stage for receiving and multiplying together each of the one or more frequency domain input signals and corresponding gain values to provide one or more processed frequency domain signals; (g) a synthesis filter for receiving the one or more processed frequency domain signals and providing a digital acoustic output signal in response; and (h) a digital-to-analog converter for receiving the digital acoustic output signal and providing the acoustic output signal in response.

Further objects and advantages of the invention will appear from the following description, taken together with the accompanying drawings.

### BRIEF DESCRIPTION OF THE DRAWINGS

In the drawings which illustrate, by way of example, preferred embodiments of the invention:

FIG. 1 illustrates a normal and three exemplary hearing impaired loudness functions;

FIG. 1A shows a normal and an exemplary hearing impaired auditory dynamic range;

FIGS. 2A and 2B show the input/output functions of a typical linear gain hearing aid and a WDRC hearing aid respectively;

FIG. 3 shows a multi-channel digital hearing aid system;

FIGS. 4A and 4B are basic block diagrams for a fixed MPO and a variable MPO volume controlled hearing aid system respectively;

FIGS. 5A and 5B are input/output functions of the systems of FIGS. 4A and 4B respectively, at low, intermediate, and high volume levels;

FIG. 6 shows target input/output responses for the hearing impaired loudness functions of FIG. 1;

FIG. 7A illustrates the basic configuration of the loudness normalization control (LNC) system according to a first embodiment of the present invention;

FIG. 7B shows a second embodiment of the loudness normalization control (LNC) system of the present invention;

FIG. 8 illustrates the operation of the LNC system of the present invention in blended compression mode; and

FIG. 9 illustrates the operation of the LNC system of the present invention in curvilinear compression mode.

### DETAILED DESCRIPTION OF THE INVENTION

A loudness function generally describes the relationship between the intensity of a sound stimulus and the subjective magnitude of that sound from an individual's perspective. Stimulus intensity is typically represented by sound pressure level which is a value in decibels (dB SPL) calculated as follows:

$$dB SPL = 20 log \frac{( Pressure of Stimulus Sound )}{( Reference Pressure )}$$

The reference pressure is typically chosen to equal 20 μPa (0.0002 μbar), but other values may also be used. The lower boundary or minimum stimulus intensity of the loudness function is the threshold of audibility for the individual—the softest sound that can be heard. The upper boundary or maximum stimulus intensity is the upper limit of comfort. This upper limit represents the loudest sound that is not uncomfortable for the individual. These limits define the dynamic range of acoustic audibility for an individual.

In clinical audiological assessments, loudness is typically measured using a categorical rating scale (category loudness scaling). The individual listener is presented with a sound (i.e. a stimulus) at various intensities, and the individual then rates the perceived loudness for each stimulus level. A proper assessment of an individual's loudness function generally requires presenting sounds at different acoustic frequencies, since the individual's response may vary with frequency. For example, if a user is to be fitted with a multi-channel digital hearing aid, the test could be performed with sounds at the centre frequency of each channel in the hearing aid system.

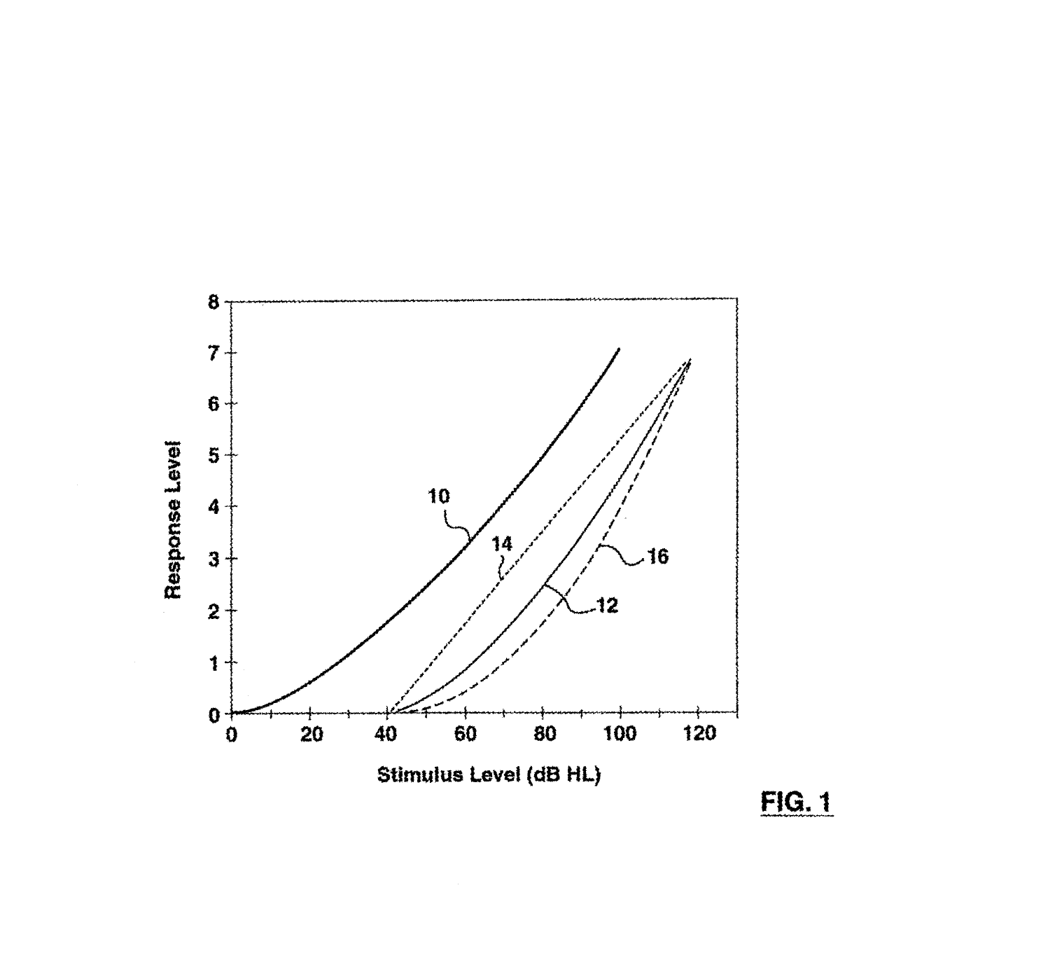

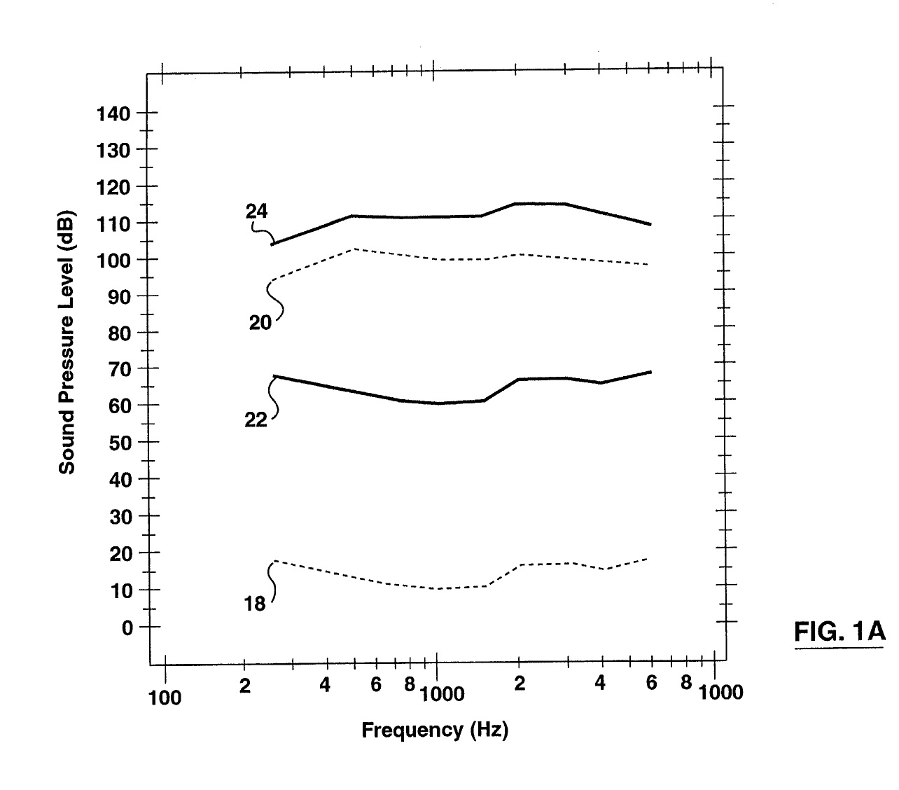

FIG. 1 shows the relationship between stimulus level and loudness rating for different hearing capabilities (i.e. different loudness functions) at a representative acoustic frequency, which for example may be 1 KHz. Note that the stimulus level in FIG. 1 is measured in dB (HL) which is equal to dB (SPL) plus a frequency dependent offset (the offset is constant for a given frequency). As shown at 10 in FIG. 1, for normal-hearing listeners this relationship is curvilinear. For many hearing impaired individuals, such as those with a sensorineural hearing loss in which hair cell function is impaired, the loudness function is said to be abnormal. Abnormal loudness functions typically differ from the norm in the following ways. First, the threshold of audibility is increased, and sounds must be presented at a greater SPL in order to be heard. Second, the upper limit of comfort is also greater, but not to the same extent as the threshold. As a result, a typical abnormal (or hearing-impaired) loudness function results in a reduction in the residual dynamic range of hearing (in other words the dynamic range of hearing of the impaired listener is compressed). This is illustrated in FIG. 1A, which shows a normal threshold of audibility 18 and a normal upper limit of comfort 20 across the acoustic frequency range, in comparison to an exemplary hearing impaired threshold of audibility 22 and upper limit of comfort 24. From FIG. 1A, the reduction in dynamic range for the hearing impaired individual is readily apparent.

A third manner in which an abnormal loudness function typically differs from a normal function is that the curvilinearity of the loudness function is usually altered. This change in curvilinearity is often referred to as abnormal loudness growth or recruitment. Generally, in an abnormal loudness function, the perceived loudness of low level signals will increase at either a slower or a faster rate than for a normal-hearing listener, resulting in a change in curvilinearity or loudness growth. FIG. 1 shows three examples of hearing-impaired loudness functions 12, 14, and 16, in addition to a normal hearing relationship 10. Of these, loudness function 12 shows the smallest degree of, i.e. minimal, abnormal loudness growth or recruitment. Loudness functions 14 and 16, on the other hand, show two relatively severe types of abnormal loudness growth. In function 14 the loudness of low level stimulus signals increases more quickly than in the loudness function 10, while in function 16 the loudness of low level stimulus signals increases more slowly than in function 10.

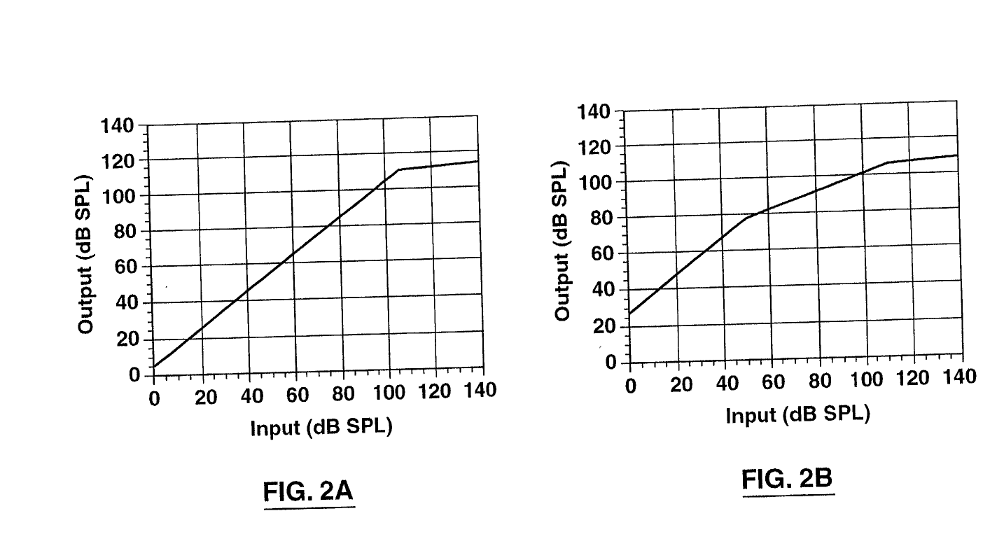

A known solution used to compensate for a listener's hearing impairment is to fit the listener with a linear gain hearing aid. The linear gain hearing aid provides a constant rate of increase in its output (i.e. a constant gain), independent of input level, until a saturation point is reached. The input/output function of a typical linear gain hearing aid is displayed in FIG. 2A. An alternative and increasingly popular compensation solution is to fit the listener with a wide dynamic range compression (WDRC) hearing aid. The gain of a WDRC hearing aid is dependent upon the input level, i.e. the WDRC hearing aid provides a variable rate of increase in its output (or gain) depending upon the input level (again until a saturation point is reached). An input/output function of a WDRC hearing aid is shown in FIG. 2B. The advantage of a WDRC hearing aid is that a larger input dynamic range is amplified (and compressed) to within the audible and comfortable loudness levels of the hearing impaired listener. Such an approach is discussed in detail in Cornelisse L. E., Seewald R. C., Jamieson D. G., “The input/output (I/O) formula: A theoretical approach to the fitting of personal amplification devices”, Journal of the Acoustical Society of America, 97(3): 1854-1864 (1995).

Generally, in order to fit the normal acoustic dynamic range into the residual dynamic or auditory range of a hearing impaired individual, both amplification and compression of the input acoustic signal will be necessary. Compression is necessary to compensate for the reduced dynamic range of the hearing impaired individual relative to a normal hearing individual's dynamic range, whereas amplification is necessary to boost sounds which would otherwise be inaudible to the hearing impaired person.

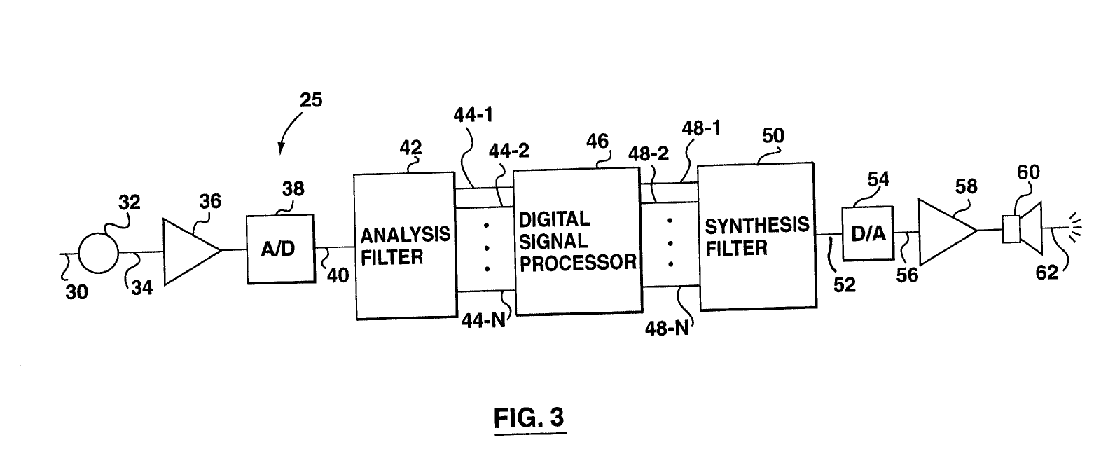

A linear gain hearing aid is generally implemented with a single channel. A WDRC hearing aid can be based on either a single-channel or a multi-channel system. In a multi-channel WDRC hearing aid, the effective frequency range or bandwidth of the hearing aid is divided into two or more channels or frequency bands. An exemplary multi-channel digital hearing aid system 25 is illustrated in FIG. 3. Referring to FIG. 3, an input acoustic or audio signal 30 is input to a microphone 32 which converts it into an electrical signal 34. The electrical signal 34 is processed through an input or pre-amplifier 36 and an analog-to-digital (A/D) converter 38 to provide a digital input signal 40. The digital input signal 40, which is a time domain signal, is transformed in known manner by an analysis filter 42 into a plurality of frequency domain signals 44-1, 44-2, . . . 44-N each of which is representative of the acoustic information content of the input signal 30 within a specific range or band of frequencies. Thus the signals 44-1, 44-2, . . . 44-N provide frequency specific information for the N channels of the digital hearing aid system and are processed independently by the digital signal processor (DSP) 46. In a single channel system (not shown), the analysis filter transforms the signal 40 into a single frequency domain signal which provides information for the entire system bandwidth which is processed by the DSP 46. Referring to FIG. 3, the processor 46 outputs a plurality of digitally processed frequency signals 48-1, 48-2,. 48-N which are combined and inverse transformed (again in known manner) by synthesis filter 50 into a digital output signal 52. The signal 52, which has been returned to the time domain, is converted into an analog output signal 56 by digital-to-analog (D/A) converter 54, and the signal 56 may then be optionally fed to an output or power amplifier 58 before being fed to a receiver or transducer 60, to provide an output audio or acoustic signal 62.

Note that the analysis filter 42 and the synthesis filter 50 in FIG. 3 may be any digital filter-bank circuits which transform a digitalized acoustic signal in the time domain to a (preferably multi-channel) frequency domain representation, and vice versa. For example, the analysis and synthesis filter-banks described in International Patent Application No. PCT/CA98/00329 (corresponding to International Publication No. WO 98/47313) may be used, the contents of that application being incorporated herein by virtue of this reference. Alternatively, in known manner, the DSP (rather than a separate filterbank coprocessor) could perform both the analysis and synthesis filtering operations. A separate coprocessor may be preferred so that different signal processing steps can be performed in parallel.

As mentioned above, each of the channels in a multi-channel hearing aid can have independent compression characteristics (for example channel gain and channel compression ratio) which may be dynamic and/or static. Therefore, wide dynamic range compression signal processing in a multi-channel system allows a hearing impaired listener to perceive loudness as a function of both frequency and input intensity level.

Some hearing aids (linear and WDRC) include a user-adjustable volume control, which is operable to increase or decrease the output level of a hearing aid. The maximum power output (MPO) of the hearing aid system can be either fixed (despite changes in volume control) or variable in that the MPO changes when the volume is adjusted. Due to the relative placement of the volume control and level detection (or power limiting) circuitry within an analog amplification circuit, a hearing aid with a fixed MPO is also referred to as an output compression hearing aid, whereas one with a variable MPO is often referred to as an input compression hearing aid.

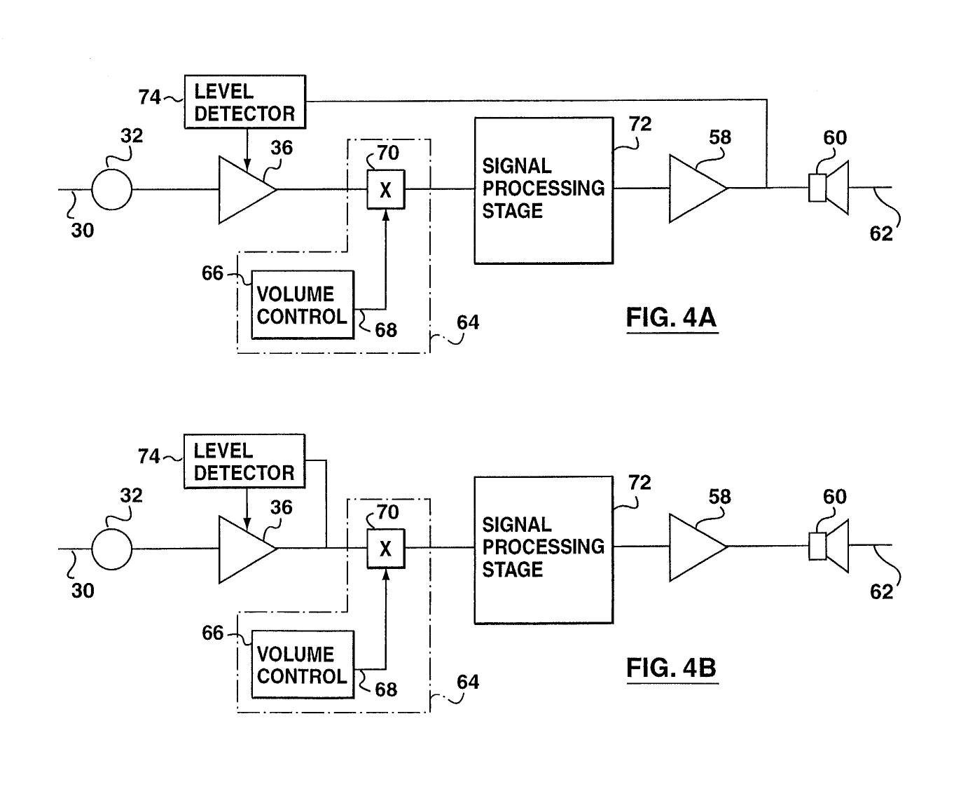

FIG. 4A shows a basic block diagram for a fixed MPO (output compression) hearing aid volume control circuit configuration, and FIG. 4B shows a basic block diagram for a variable MPO (input compression) volume control configuration. In each circuit, an input acoustic or audio signal 30 is processed through a microphone 32, a pre-amplifier 36, a volume control stage 64, a signal processing stage 72, a power amplifier 58, and a receiver 60 so as to provide an output acoustic or audio signal 62 to the user/wearer of the hearing aid. The signal processing stage 72 can comprise any suitable acoustic signal processing system such as, for instance, that described with respect to references 38, 42, 46, 50, and 54 in FIG. 3. However, the signal processing stage 72 could in general be any analog or digital processing system designed to process an acoustic signal. The volume control stage 64 comprises a volume control/adjust unit 66 which can be manipulated to generate a volume control signal 68 which is used to vary, via multiplier 70, the level of the signal output of the preamplifier 36, as desired by a user of the hearing aid.

In addition, in each of FIGS. 4A and 4B, the gain of the pre-amplifier 36 is controlled by a level detector circuit 74. For the output compression (fixed MPO) circuit of FIG. 4A, the level detector circuit 74 limits the MPO by controlling amplifier 36 in response to the level of the output of the amplifier 58—i.e. the output of amplifier 58 is limited. For the input compression (variable MPO) circuit of FIG. 4B, the level detector circuit 74 limits the MPO by controlling amplifier 36 in response to the level of the output of the amplifier 36—i.e. the output of amplifier 36 is limited. Thus, for the circuit of FIG. 4B, the limiting of the power in the system takes place independently of any changes in volume control at 64 and so the circuit has a variable MPO.

Note that, as shown in FIGS. 4A and 4B, the volume control stage 64 of prior art hearing aid systems, is implemented in the analog domain. Thus when the signal processing stage 72 involves digital processing techniques, the volume control stage 64 is implemented in such a manner as to mimic an analog volume control.

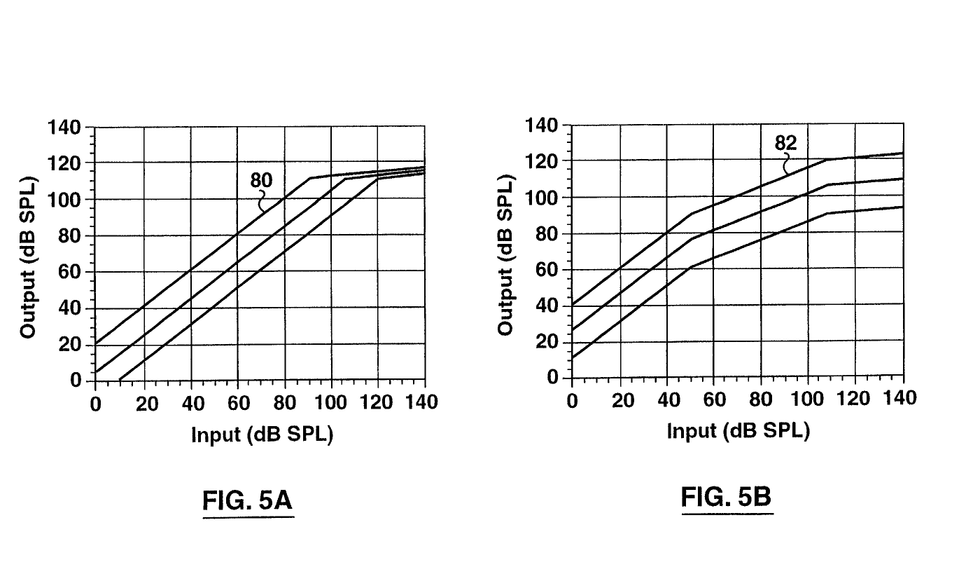

Linear gain hearing aids are typically provided with an output compression volume control, while WDRC hearing aids (which generally have a lower gain than linear aids for high level inputs) are usually provided with an input compression volume control. FIGS. 5A and 5B show input/output responses which illustrate the effect of volume control changes on the output of a linear gain hearing aid with output compression (FIG. 5A) and the output of a WDRC hearing aid with input compression (FIG. 5B). The three curves in each of FIGS. 5A and 5B represent the input/output response of the hearing aid at a low, intermediate, and high volume setting.

A disadvantage associated with a fixed MPO (output compression) hearing aid is that if the listener increases the gain by increasing the volume control setting, the hearing aid may prematurely saturate and cause distortion. This is illustrated in FIG. 5A for loudness response 80 with the volume set at the highest level. On the other hand, if the listener increases the gain of a variable MPO (input compression) hearing aid by increasing the volume control setting, the MPO will also increase and potentially cause discomfort and possibly even harm to the listener. The potential increase in MPO is illustrated in FIG. 5B by loudness response 82 which again is representative of the highest volume setting.

In prior art WDRC hearing aid systems which do have volume control, the effect of the volume control is independent of the input level, so that a particular volume adjustment simply adds or subtracts a fixed amount of dB, as shown in FIG. 5B. As a result, prior WDRC hearing aids with volume control apply a volume gain independently of and separately from the compression ratio.

In prior art fitting procedures, the loudness perception of a hearing-impaired individual is first measured. Next, gain (as a function of input level) is calculated so as to provide the difference between an average normal-hearing loudness function and the hearing-impaired listener's loudness function. While this gain is programmable during the fitting procedure, it is not thereafter adjustable by a user.

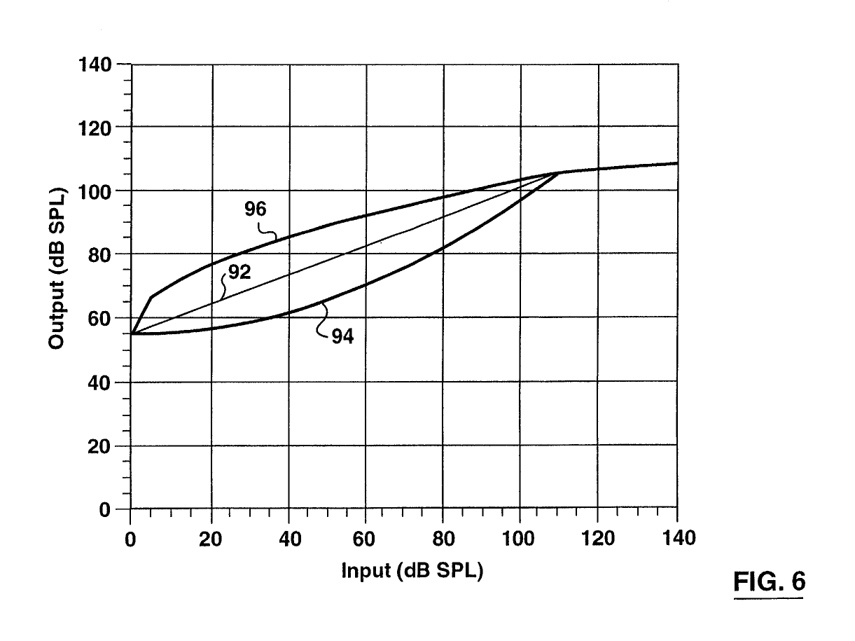

FIG. 6 shows target input/output compression responses for the three hearing impaired loudness functions of FIG. 1 (again at a representative frequency). The target responses 92, 94 and 96 are intended to “fit” the loudness functions 12, 14, and 16 of FIG. 1 respectively. As illustrated in FIG. 6, when the growth of the hearing-impaired listener's loudness function is different from the growth of the normal-hearing loudness function so that the listener's loudness function has abnormal loudness growth, then the target input/output response or compression is curvilinear or non-linear.

Most hearing aids only provide a linear compression characteristic, but hearing aid devices with a linear compression characteristic (i.e. a constant compression ratio in the compression region) will not adequately restore normal loudness perception where the user's loudness growth is abnormal. Currently, very few hearing aids have been designed to provide a curvilinear compression characteristic in which the compression ratio varies as a function of the input signal level over the input range of the compression region. Furthermore, prior art hearing aids which do provide such compression, do not include a user control for adjusting the curvilinearity of the compression characteristics over the input dynamic range (i.e. of the input/output function).

As a result, a major drawback associated with the above fitting procedures is the requirement of first measuring the loudness perception of a hearing-impaired individual. This is not only time-consuming but is also only an estimation which may be inaccurate at the outset or may become inaccurate over time. Moreover, loudness perception test procedures are very time consuming, and not all users can properly perform them. Also, as described, analog volume controllable hearing aid devices having an input or output compression characteristic may not match the user or wearer's preferred listening levels and can result in distortion of the input signal or harm to the hearing aid wearer. These problems are overcome in the present invention by the user adjustable loudness normalization control feature which allows the user to adjust the compression characteristics of the hearing aid to provide the user with optimal acoustic compensation.

As discussed, prior art user-adjustable volume controls in hearing aids are generally implemented with analog amplification circuitry, and are thus constrained by the limitations of analog control. The present invention, provides a user adjustable loudness control system which uses a digital signal processor with a programmable compression characteristic. The user control system is programmed so that the hearing aid user/wearer can adjust the output of the hearing aid to achieve comfortable loudness perception, to optimally restore the loudness function to normal loudness growth. Preferably, the user adjustable loudness control is capable of providing a different mode of operation in various frequency regions. In this manner, the control provides independent characteristics for each channel in a multi-channel hearing aid system.

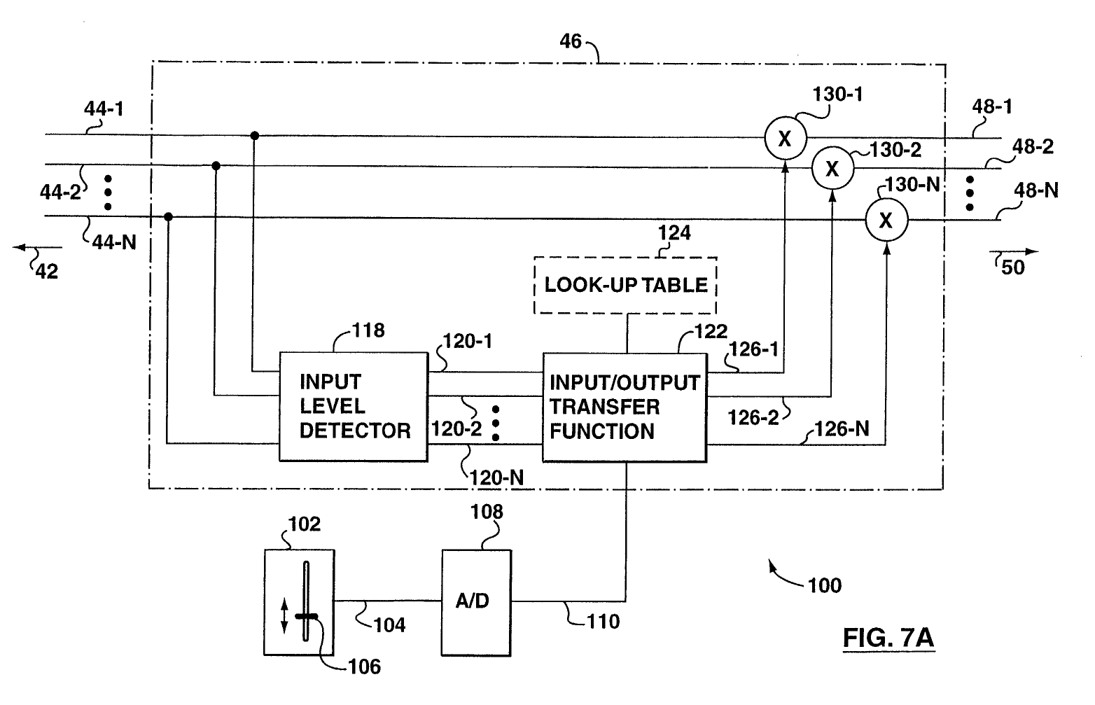

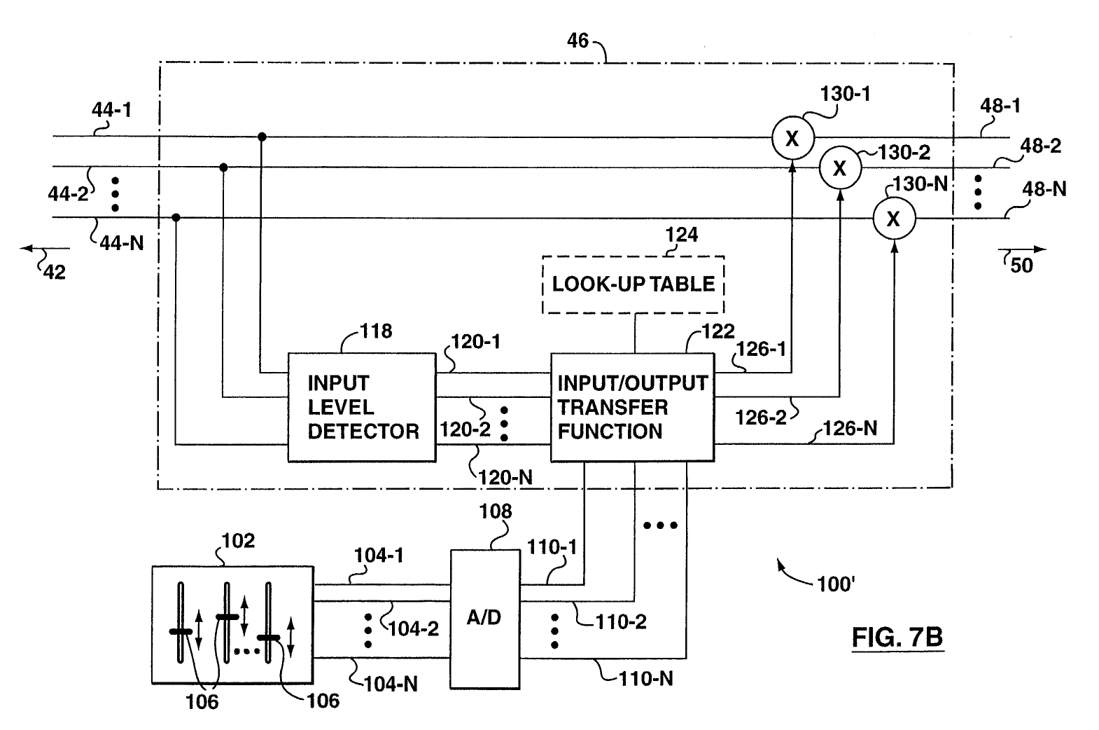

FIG. 7A shows a basic configuration of the loudness normalization control (LNC) system 100 in accordance with a preferred embodiment of the present invention. Although the system 100 may generally form part of a digital hearing aid or other amplification device, the LNC system of FIG. 7A is shown implemented within the multi-channel digital hearing aid system of FIG. 3. An analog LNC signal 104 is produced by an LNC adjustment unit 102. The adjustment unit 102 includes means 106 for controllably adjusting or setting the LNC signal 104. As will be obvious to those skilled in the art, the adjusting means 106 for each signal 104 may comprise any device capable of being manipulated by a human user or operator (not shown), such as a potentiometer with a slidable wiper arm or rotatable dial, or dial pad buttons which respectively increase and decrease the magnitude of the corresponding LNC signal. Alternatively, the adjusting means could be voice-activated or responsive to a remotely generated radio signal from a remote control unit. In general, any means which serves to provide an adjustable digital control signal may be used.

The LNC signal 104 is converted by an A/D converter 108 into a corresponding digital LNC signal 110 before being fed to the digital signal processor (DSP) 46 of the digital hearing aid. As previously described in connection with FIG. 3, the DSP 46 receives a plurality of frequency domain signals 44-1, 44-2, . . . 44-N from the analysis filter-bank (at 42 in FIG. 3) which, as indicated, may be as described in International Patent Application No. PCT/CA98/00329 (corresponding to International Publication No. WO 98/47313). Each of the frequency domain signals 44, being representative of the acoustic information content of the acoustic input signal within a specific channel or frequency band, has its level (or magnitude) detected by an input level detector block 118. The level detector block may comprise a function programmed in the DSP which receives the signals 44 and returns the signals 120 in response. Signals 120 1, 120-2, . . . 120-N, indicative of the level of each of the respective frequency domain signals 44, are fed to an input/output transfer function block 122 which is modeled by an algorithm running in the core of DSP 46. A gain value 126-1, 126-2, . . . 126-N for each of the frequency domain signals 44 is calculated or determined in block 122 based on the input level signals 120 and the LNC signal 110. As discussed below, in the multi-channel system, the effect of the LNC signal 110 is generally different for each channel in the system. The gain values 126 are applied to the frequency domain signals 44 via multipliers 130-1, 130-2, . . . 130-N respectively to provide the processed frequency signals 48-1, 48-2, . . . 48-N which are provided to a synthesis filter 50 and subsequently an acoustic time domain output signal is generated (as shown in FIG. 3). The synthesis filter 50 may again be as described in International Patent Application No. PCT/CA98/00329 (corresponding to International Publication No. WO 98/47313).

FIG. 7B shows a LNC system 100′ according to a second embodiment of the present invention in which a plurality of analog LNC signals 104-1, 104-2, . . . 104-N originate from the LNC adjustment unit 102. In this embodiment, a separate LNC signal is provided for controlling each channel in a multi-channel system. The adjustment unit 102 includes a separate means 106 for controllably adjusting or setting each of the LNC signals 104-1, 104-2, . . . 104-N. The LNC signal 104 are converted by an A/D converter 108 into a corresponding digital LNC signals 110-1, 110-2, . . . 110-N before being fed to the digital signal processor (DSP) 46 of the digital hearing aid system. In this embodiment, the gain value 126-1, 126-2, . . . 126-N for each of the frequency domain signals 44 is determined in block 122 based on the input level signals 120 and the corresponding LNC signal 110. Because of the additional complexity, this multi-control embodiment of the LNC system is more suitable for an amplification device such as a portable stereo system rather than for a digital hearing aid system. However, the multi-control embodiment could also be implemented in a hearing aid.

In another embodiment of the LNC system (not shown), a single LNC adjustment means 106 generates a different LNC signal for each channel in a multi-channel amplification device. In this embodiment, the adjustment unit 102 may be integrated with A/D converter 108 and may optionally also include a separate co-processor for generating the different control signals in response to the adjustment means.

The LNC system may also be implemented in a single channel hearing aid (or amplification device). It will be clear to those skilled in the art that the LNC system as illustrated in FIG. 7A can be easily reduced to a single channel hearing aid implementation by simply using a analysis (and corresponding synthesis) filter which provides only one frequency domain signal and by processing this frequency domain signal in response to the level of that signal and the LNC signal. Moreover, in a multi-channel system, several frequency domain signals can also be combined in the frequency domain (in various ways known to those skilled in the art) to generate a single broadband frequency domain signal which is subsequently processed. In this manner, a multi-channel device can also act as though it were a single channel device.

In all of the above described embodiments, the algorithm providing the input/output transfer function 122 may determine the output (i.e. the gain signal 126) based on a look-up table 124 stored in non-volatile memory, so that the contents of the look-up table remain in memory even when the DSP 46 is powered down. Alternatively, a fitting formula function could be directly programmed in the DSP, or a combination of a look-up table and fitting formula algorithms can be used. Both of these options provide good flexibility.

If the algorithm for the input/output transfer function 122 uses a look-up table 124 to determine the LNC gain value for each channel in the system, it may do so based upon indexed values of the LNC signal or setting 110 for the channel, the input level 120 of the channel, and the specific frequency channel. As will be understood, separate look-up tables can also be provided in the DSP 46, such as a specific table for each frequency channel (or a specific table for each volume control setting in embodiments in which more than one LNC signal is used).

Where the algorithm for transfer function 122 uses a fitting formula, then the parameters in the formula will include the LNC signal 110, the input level 120 for the channel, and one or more parameters relating to the specific frequency channel. Again it is possible for different formulas to be used—for example, a different formula for each frequency channel. Furthermore, as indicated, algorithms based on both look-up tables and fitting formulas can be used. For instance, a look-up table can be used to compute an initial gain value 126 based on the LNC setting 110 and subsequently a mathematical fitting formula is used to modify this gain value based on the input level 120 and the frequency channel. This mixed algorithm technique for the input/output transfer function 122 is preferred since it provides greater flexibility in the performance of the control. For example, a smaller lookup table can be used with subsequent smoothing calculations carried out to provide a smooth input/gain function.

The effect of the LNC signal on the input/output characteristic is dependent upon (1) the input level of the signal and (2) the programmed compression characteristics, including the taper. The taper of the LNC control reflects the effect of the control over the entire acoustic range of operation.

In a multi-channel system, the effect of the LNC signal(s) will also be dependent on the particular frequency channel. The loudness normalization control system of the present invention allows the input/output characteristics of the individual channels to be distinctly affected by the control. Therefore, each channel has a separate input/output characteristic which when combined together form an overall or composite characteristic.

As a result, the input/output compression characteristic of the LNC system 100 may, for instance, simulate an analog input compression system, an analog output compression system, or a blended compression system which combines the advantageous features of both the input and output compression systems. The blended mode simplifies calculations and so is a convenient way to implement a curvilinear characteristic. In addition, the compression characteristic may be adjusted in either a “true curvilinear” fashion or as a stepped linear approximation to a curvilinear characteristic. The curvilinear and step-linear approximation to curvilinear modes may be implemented in either a single channel or a multi-channel digital WDRC hearing aid. In general, the LNC system can be adjusted to provide numerous different modes of operation for either a single or multi-channel system.

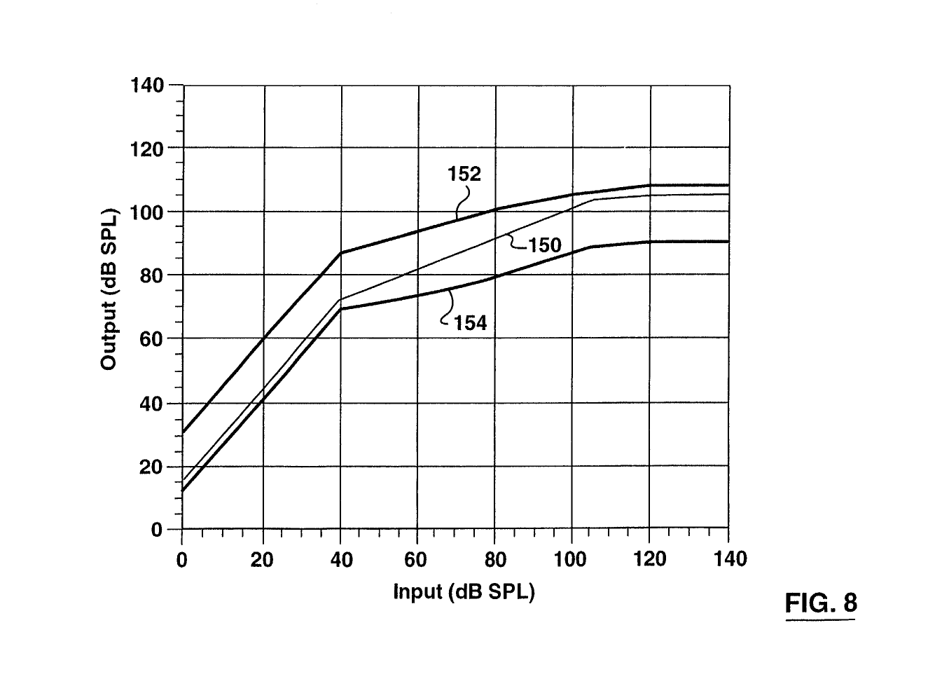

FIG. 8 illustrates the effect of a single channel LNC user control system according to the present invention in the blended (stepped linear approximation) compression mode (note that FIG. 8 could also illustrate the response of a single channel in a multi-channel system). The input/output response 150 shown in FIG. 8 represents a WDRC hearing aid at a “normal” loudness normalization control setting. The input/output response 152 shows the effect of increasing the LNC setting and the response 154 shows the effect of decreasing the control setting. Referring to FIG. 8, when the LNC control is increased (152) the output for high level input signals is only slightly increased from the normal setting 150. Since the compression ratio for response 152 increases as the input (sound pressure) level gets stronger, the potential distortion associated with fixed (output compression) hearing aid systems and the potential discomfort associated with variable MPO (input compression) systems, as illustrated in FIGS. 5A and 5B, are avoided. When the LNC setting is decreased (154), the output for low level input signals is only slightly decreased as compared to the normal setting 150. This is advantageous as it maintains the hearing threshold level of the user at a low input level, despite the fact that the LNC setting has been reduced, unlike prior art volume control systems. Thus, in FIG. 8 the largest effect of adjusting the LNC setting occurs for mid-level inputs, i.e. within the compression region or stage of the input/output response.

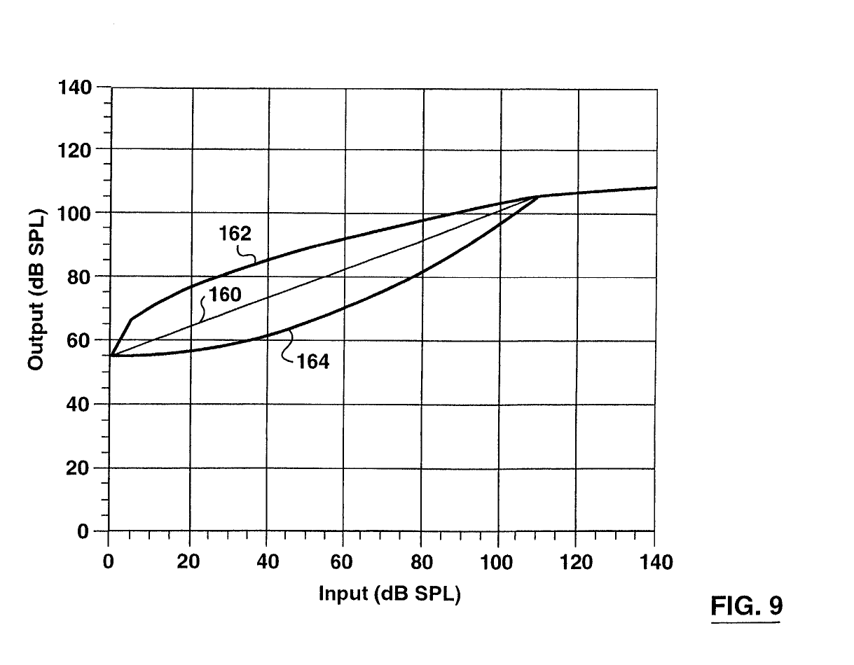

FIG. 9 illustrates the effect of a single channel LNC user control in the “true curvilinear” compression mode. Unlike the blended compression control illustrated in FIG. 8, the maximum output level does not change in the “true curvilinear” compression mode of FIG. 9. The response 160 represents the input/output characteristic at a “normal” LNC setting, whereas the responses 162 and 164 represent responses at higher and lower LNC settings respectively. Once again the prior art problems associated with fixed and variable MPO systems are not present. In addition, as illustrated in FIG. 9, the curvilinearity of the compression characteristic can be adjusted by the user to compensate for (or normalize) a large range of abnormal loudness growth functions, such as the functions 14 and 16 in FIG. 1 (whose target responses are shown at 94 and 96 respectively in FIG. 6). Once again, in this mode the largest effect of adjusting the LNC setting occurs for mid-level input signals. Significant effects also occur for lower input levels (except for the very lowest levels) when adjusting the LNC setting.

The loudness normalization control system 100 of the present invention eliminates the time-consuming, laborious, and often inaccurate step of measuring loudness data for a particular hearing-impaired user. Instead, for example, the LNC system of the present invention permits the use of an initial fitting which only measures threshold data for the individual (i.e. the threshold of audibility and the upper limit of comfort), and then estimates loudness based on average or statistical data. In operation, the hearing impaired user is then free to adjust the curvilinearity of his or her loudness response to optimize the output of the device from the user's perspective.

Although the above description of the LNC system has been made primarily in connection to a digital hearing aid device, it will be clear that the LNC system may be used with any type of personal amplification device such as a portable stereo system, telephone receiver, auxiliary television unit, or the like.

Furthermore, while preferred embodiments of the invention have been described, these are illustrative and not restrictive, and the present invention is intended to be defined by the appended claims.

I claim:

1. A method of generating an analog acoustic output signal from an acoustic input signal in accordance with a configurable input/output characteristic, said method comprising the steps of:
(a) converting the acoustic input signal into a digital acoustic input signal;
(b) transforming the digital acoustic input signal into one or more frequency domain input signals;
(c) detecting the magnitude of each of the one or more frequency domain input signals;
(d) providing an adjustable digital loudness normalization control signal for controlling the configuration of said input/output characteristic;
(e) for each of the one or more frequency domain input signals, determining a gain value in response to the loudness normalization control signal and the magnitude of the frequency domain input signal;
(f) providing one or more frequency domain output signals by multiplying each of the frequency domain input signals by the corresponding gain value;
(g) transforming the one or more frequency domain output signals into a digital acoustic output signal; and
(h) converting the digital acoustic output signal into the analog acoustic output signal.

2. A method according to claim 1 further comprising the step of (i) independently adjusting the digital loudness normalization control signal to configure the configurable input/output characteristic in accordance with the preferences of a hearing impaired individual.

3. A method according to claim 1 comprising performing steps (c), (e), and (f) by means of a programmable digital signal processor.

4. A method according to claim 3 wherein step (e) comprises calculating the corresponding gain value for each of the one or more frequency domain input signals by means of a fitting formula programmed into said programmable digital signal processor.

5. A method according to claim 3 wherein step (e) comprises determining the corresponding gain value for each of the one or more frequency domain input signals by means of a look-up table stored in said programmable digital signal processor.

6. A method according to claim 5 wherein said look-up table is stored in non-volatile memory in said programmable digital signal processor.

7. A method according to claim 3 wherein step (e) comprises determining the corresponding gain value for each of the one or more frequency domain input signals by means of a fitting formula programmed into said programmable digital signal processor and a look-up table.

8. A method according to claim 7 wherein said look-up table is stored in non-volatile memory in said programmable digital signal processor.

9. A method according to claim 1 wherein step (b) comprises transforming the digital acoustic signal into at least two frequency domain input signals, each of said frequency domain input signals having a configurable channel input/output characteristic associated therewith, said configurable channel input/output characteristics together forming said configurable input/output characteristic, and wherein said at least two frequency domain input signals are provided with different channel input/output characteristics.

10. A method according to claim 1 wherein said configurable input/output characteristic is a curvilinear compression characteristic.

11. A method according to claim 1 wherein said configurable input/output characteristic is an input compression characteristic.

12. A method according to claim 1 wherein said configurable input/output characteristic is an output compression characteristic.

13. A method of generating an acoustic output signal from an acoustic input signal in accordance with a configurable composite input/output characteristic, said method comprising the steps of:
(a) converting the acoustic input signal into a digital acoustic input signal;
(b) transforming the digital acoustic input signal into N frequency domain input signals, N being a positive integer greater than or equal to two;
(c) detecting the magnitude of each of the N frequency domain input signals;
(d) providing N adjustable digital loudness normalization control signals for controlling said configuration of said configurable composite input/output characteristic, each of the loudness control signals corresponding to one of the frequency domain input signals;
(e) determining N gain values, each of said gain values corresponding to one of said frequency domain input signals and each of said gain values being determined in response to one of said frequency domain input signals and to one of said adjustable digital loudness normalization control signals;
(f) multiplying each frequency domain input signal by its corresponding gain value to provide N processed frequency domain signals;
(g) transforming the N processed frequency domain signals into a digital acoustic output signal; and
(h) converting the digital acoustic output signal into the acoustic output signal.

14. A method according to claim 13 further comprising the step of (i) differentially adjusting the N digital loudness normalization control signals in accordance with the preferences of a hearing impaired individual.

15. A method according to claim 13 comprising performing steps (c), (e), and (f) by means of a programmable digital signal processor.

16. A method according to claim 5 wherein said look-up table is stored in non-volatile memory coupled to said programmable digital signal processor.

17. A method according to claim 7 wherein said look-up table is stored in non-volatile memory coupled to said programmable digital signal processor.

18. A method according to claim 9 wherein each of said configurable channel input/output characteristics may be varied by adjusting said adjustable digital loudness normalization control signal.

19. A method according to claim 2 wherein the curvilinearity of said configurable input/output characteristic may be varied by adjusting said adjustable digital loudness normalization control signal.

20. A method according to claim 1 wherein said configurable input/output characteristic is a combination of two or more of:
(a) a curvilinear compression characteristic;
(b) an input compression characteristic; or
(c) an output compression characteristic.

21. A method according to claim 15 wherein step (e) comprises calculating the corresponding gain value for each of the one or more frequency domain input signals by means of a fitting formula programmed into said programmable digital signal processor.

22. A method according to claim 15 wherein step (e) comprises determining the corresponding gain value for each of the one or more frequency domain input signals by means of a look-up table.

23. A method according to claim 22 wherein said look-up table is stored in non-volatile memory in said programmable digital signal processor.

24. A method according to claim 22 wherein said look-up table is stored in non-volatile memory coupled to said programmable digital signal processor.

25. A method according to claim 15 wherein step (e) comprises determining the corresponding gain value for each of the one or more frequency domain input signals by means of a fitting formula programmed into said programmable digital signal processor and a look-up table.

26. A method according to claim 25 wherein said look-up table is stored in non-volatile memory in said programmable digital signal processor.

27. A method according to claim 25 wherein said look-up table is stored in non-volatile memory coupled to said programmable digital signal processor.

28. A method according to claim 13 wherein said configurable input/output characteristic is a curvilinear compression input/output characteristic.

29. A method according to claim 13 wherein said configurable input/output characteristic is an input compression input/output characteristic.

30. A method according to claim 13 wherein said configurable input/output characteristic is an output compression input/output characteristic.

31. A method according to claim 13 wherein the curvilinearity of said configurable input/output characteristic varies in response to a change in one or more of said adjustable digital loudness normalization control signal.

32. A method according to claim 14 wherein the magnitude of said gain values varies differentially in response to said differential adjustment of said digital loudness normalization control signals.

33. A signal processing apparatus comprising:
(a) an analysis filter for receiving a digital acoustic input signal and for providing N frequency domain input signals, wherein N is a positive integer;
(b) a loudness normalization adjustment stage for controllably providing a digital loudness normalization control signal;
(c) an input level detector coupled to said analysis filter for receiving said N frequency domain input signals and for providing N input level signals, each of said input level signals corresponding to one of said frequency domain input signals;
(d) an input/output transfer function stage coupled to said input level detector and to said loudness normalization adjustment unit for providing N gain signals in response to said digital loudness normalization control signal and said input level signals, each of said gain signals corresponding to one of said frequency domain input signals;
(e) a multiplier stage coupled to said analysis filter and to said input/output transfer function stage for providing N frequency domain output signals in response to said frequency domain input signals and said gain signals; and
(f) a synthesis filter for receiving said N frequency domain output signals and for providing a digital acoustic output signal.

34. The apparatus of claim 33 wherein N is equal to or greater than two.

35. The apparatus of claim 34 wherein said input/output transfer function stage is configured to vary at least one of said gain signals by an amount different from at least one other of said gain signals in response to a change in said loudness normalization control signal.

36. The apparatus of claim 34 wherein said digital loudness normalization control signal comprises up to N channel digital loudness normalization control signals, each of said channel digital loudness normalization control signals corresponding to one or more of said input level signals.

37. The apparatus of claim 34 wherein said digital loudness normalization control signal comprises N channel digital loudness normalization control signals, each of said channel digital loudness normalization signals corresponding to one of said N input level signals.

38. The apparatus of claim 34 wherein said input/output transfer function stage includes a look-up table for determining the magnitude of at least one of said gain signals.

39. The apparatus of claim 34 wherein said input/output transfer function stage is configured to determine the gain value of at least one of said gain signals according to a fitting formula.

40. The apparatus of claim 34 wherein said input/output transfer function stage includes a look-up table and is configured to determine the gain value of at least one of said gain signals by means of a fitting formula and said look-up table.

41. The apparatus of claim 33 wherein said loudness normalization adjustment stage includes a signal controlling device for controlling said digital loudness normalization control signal.

42. The apparatus of claim 40 wherein said signal controlling device is a variable resistor.

43. The apparatus of claim 40 wherein said signal controlling device is a two-way momentary switch, wherein movement of the switch in a first direction causes the magnitude of said digital loudness normalization control signal to increase and movement of the switch in a second direction causes the magnitude of said digital loudness normalization control signal to decrease.

44. The apparatus of claim 41 wherein said signal controlling device may be manipulated by a user of said apparatus.

45. The apparatus of claim 34 wherein said N gain signals define an input/output characteristic correlating said digital acoustic input signal and said digital acoustic output signal and wherein said input/output characteristic is a curvilinear compression characteristic.

46. The apparatus of claim 34 wherein said N gain signals define an input/output characteristic correlating said digital acoustic input signal and said digital acoustic output signal and wherein said input/output characteristic is a stepped linear approximation of a curvilinear compression characteristic.

47. The apparatus of claim 34 wherein said N gain signals define an input/output characteristic correlating said digital acoustic input signal and said digital acoustic output signal and wherein said input/output characteristic is an input compression characteristic.

48. The apparatus of claim 34 wherein said N gain signals define an input/output characteristic correlating said digital acoustic input signal and said digital acoustic output signal and wherein said input/output characteristic is an output compression characteristic.

49. The apparatus of claim 34 wherein said N gain signals define an input/output characteristic correlating said digital acoustic input signal and said digital acoustic output signal and wherein said input/output characteristic is a combination of two or more of:
(a) one of (A) a curvilinear compression characteristic or (B) a stepped linear approximation of a curvilinear compression characteristic;
(b) an input compression characteristic; or
(c) an output compression characteristic.

50. The apparatus of claim 33 wherein said level detector, said input/output transfer function stage and said multiplier stage are implemented in a programmable digital signal processor.

51. The apparatus of claim 50 wherein said input/output transfer function stage includes a look-up table for determining the magnitude of at least one of said gain signals.

52. The apparatus of claim 50 further comprising a non-volatile memory coupled to said digital signal processor and wherein a look-up table is recorded in said non-volatile and wherein said input/output transfer function utilizes said look-up table for determining the magnitude of at least one of said gain signals.

53. The apparatus of claim 50 wherein said input/output transfer function stage is configured to determine the gain value of at least one of said gain signals according to a fitting formula.

54. The apparatus of claim 50 wherein said input/output transfer function stage includes a look-up table and is configured to determine the gain value of at least one of said gain signals by means of a fitting formula and said look-up table.

55. The apparatus of claim 50 further comprising a non-volatile memory coupled to said digital signal processor and wherein a look-up table is recorded in said non-volatile and wherein said input/output transfer function is configured to determine the gain value of at least one of said gain signals by means of a fitting formula and said look-up table.

56. The apparatus of claim 33 further comprising:
(a) a microphone for receiving an input sound energy signal and for providing an analog input acoustic signal;
(b) a A/D converter coupled to said sound reception device for receiving said analog input acoustic signal or an image of said analog input acoustic signal and coupled to said analysis filter for providing said digital acoustic input signal;
(c) a D/A converter coupled to said synthesis filter for receiving said digital output acoustic signal and for providing an analog output acoustic signal; and
(d) a speaker coupled to said D/A converter for receiving said analog output acoustic signal and providing an output sound energy signal.
